(19) United States
(12) Patent Application Publication
(10) Pub. No.: US 2025/0300623 A1
(43) Pub. Date: Sep. 25, 2025

(54) PACKAGED MODULES HAVING FILTER FAN OUT SUBSTRATE

(71) Applicant: SKYWORKS SOLUTIONS, INC., Irvine, CA (US)

(72) Inventors: Howard E. CHEN, Anaheim, CA (US); Sundeep Nand NANGALIA, Raleigh, NC (US)

(21) Appl. No.: 19/087,390

(22) Filed: Mar. 21, 2025

Related U.S. Application Data
(60) Provisional application No. 63/568,975, filed on Mar. 22, 2024.

(51) Int. Cl. H03H 9/10; H03H 3/02

(52) U.S. Cl. CPC H03H 9/1042; H03H 3/02

(57) ABSTRACT

A packaged module can include a substrate having first and second sides, and a plurality of redistribution layers. The packaged module can further include a filter die implemented on the first side of the substrate, and a plurality of pins implemented on the second side of the substrate, such that the redistribution layers include a fan out circuit between the filter die and the pins. The packaged module can further include a passive element implemented as part of the redistribution layers and configured to support operation of the filter die.

### CROSS-REFERENCE TO RELATED APPLICATION(S)

This application claims priority to U.S. Provisional Application No. 63/568,975 filed Mar. 22, 2024, entitled PACKAGED MODULES HAVING FILTER FAN OUT SUBSTRATE, the disclosure of which is hereby expressly incorporated by reference herein in its respective entirety.

### BACKGROUND

### Field

The present disclosure relates to packaged electronic modules such as packaged modules for radio-frequency applications.

### Description of the Related Art

In many electronics applications, radio-frequency (RF) circuits and/or circuit elements are implemented as parts of packaged modules. A packaged module typically includes a packaging substrate configured to receive and support a plurality of components such as semiconductor die and/or circuit elements such as discrete passive components. In some applications, such a packaged module can include one or more of the foregoing devices mounted on one side of the packaging substrate, and the other side can be provided with mounting structures such as a ball grid array.

### SUMMARY

In accordance with a number of implementations, the present disclosure relates to a packaged module that includes a substrate having first and second sides, and a plurality of redistribution layers. The packaged module further includes a filter die implemented on the first side of the substrate, and a plurality of pins implemented on the second side of the substrate, such that the redistribution layers include a fan out circuit between the filter die and the pins. The packaged module further includes a passive element implemented as part of the redistribution layers and configured to support operation of the filter die.

In some embodiments, the packaged module can further include a mold structure implemented on the first side of the substrate to at least partially encapsulate the filter die. In some embodiments, the mold structure can be configured to completely encapsulate the filter die.

In some embodiments, the mold structure can be configured to expose a back side of the filter die. The mold structure can include a surface that exposes the back side of the filter die, with the surface of the mold structure being formed from a thinning operation. The exposed back side of the filter die can be formed from removal of at least some material from the back side of the filter die. The exposed back side of the filter die and the surface of the mold structure can be substantially co-planar.

In some embodiments, the mold structure can be formed from a low pressure liquid molding process.

In some embodiments, the plurality of redistribution layers can include a first outermost layer that defines the first side and a second outermost layer that defines the second side. The filter die can be implemented directly on the first side, and the pins can be implemented directly on the second side.

In some embodiments, the pins can be implemented as ball-shaped structures such as solder balls. In some embodiments, the pins can be implemented as metal posts such as copper posts.

In some embodiments, the filter die can be mounted on the first side of the substrate to provide a no-gap configuration therebetween. The filter die includes a mounting side that is patterned to allow the mounting side to be mated directly with a corresponding patterned area on the first side of the substrate.

In some embodiments, the passive element can be implemented as one or more features printed on one or more layers of the redistribution layers.

In some embodiments, the passive element can include an inductor, a capacitor or a resistor. The passive element can be configured to provide a radio-frequency functionality with respect to the filter die. The radio-frequency functionality can include a matching functionality. In some embodiments, the passive element can be configured to provide a radio-frequency functionality with a desired quality factor.

In some embodiments, the passive element can be implemented on a selected layer of the redistribution layers. In some embodiments, the selected layer can include a layer at or closest to the first side of the substrate. In some embodiments, the selected layer can include a layer adjacent to a layer associated with the first side of the substrate.

In some embodiments, the packaged module can further include another passive element implemented as part of the redistribution layers and configured to support operation of the filter die. In some embodiments, the passive element and the other passive element can be implemented on a common layer. In some embodiments, the passive element and the other passive element can be implemented on different layers.

In some embodiments, the passive element can be implemented to provide a lateral footprint that at least partially overlaps with a lateral footprint of the filter die to allow reduction of lateral dimensions of the packaged module.

In some embodiments, the filter die can be implemented as an acoustic wave filter die. In some embodiments, the acoustic wave filter die can include a surface acoustic wave (SAW) filter, a bulk acoustic wave (BAW) filter, or a multilayer piezoelectric substrate (MPS) filter.

In some embodiments, the packaged module can further include another filter die implemented on the first side of the substrate. In some embodiments, each of the filter die and the other filter die can be implemented as an acoustic wave filter die. In some embodiments, the acoustic wave filter die and the other acoustic wave filter die can be implemented as same type of acoustic wave filter device. In some embodiments, the acoustic wave filter die and the other acoustic wave filter die can be implemented as different types of acoustic wave filter devices.

In some implementations, the present disclosure relates to a method for manufacturing a packaged module. The method includes providing a carrier, forming a first-side portion of a module on the carrier, and removing the carrier from the first-side portion to provide a surface. The method further includes providing or forming a substrate having redistribution layers on the first-side portion, such that the redistribution layers include a passive element, and such that a first side of the substrate engages the surface of the first-side portion and a second side of the substrate is opposite from the first side. The method further includes forming a second-side portion of the module on the second side of the substrate.

In some embodiments, the forming of the first-side portion can include attaching a filter die on a surface of the carrier, and forming a mold structure over the surface of the carrier to at least partially encapsulate the filter die. The forming of the mold structure can result in the mold structure fully encapsulating the filter die.

In some embodiments, the forming of the mold structure can result in the mold structure exposing a back side of the filter die. The forming of the mold structure can include a mold forming process that results in the mold structure fully encapsulating the filter die, and a thinning process that results in the mold structure being thinned to expose the back side of the filter die. The thinning process can include a grinding process. The thinning process can result in the exposed back side of the filter die being formed from removal of at least some material from the back side of the filter die. The thinning process can result in the exposed back side of the filter die and the surface of the mold structure being substantially co-planar.

In some embodiments, the removing of the carrier from the first-side portion can include a debonding process.

In some embodiments, the substrate can be a pre-fabricated substrate having multiple layers such that a first outermost layer defines the first side and a second outermost layer defines the second side. In some embodiments, the first side of the substrate can directly engage the surface of the first-side portion. In some embodiments, the first side of the substrate can engage a mounting surface of a filter die of the first-side portion to provide a gapless interconnect between the filter die and the first side of the substrate.

In some embodiments, the substrate can be formed over the surface of the first-side portion. The forming of the substrate can include forming multiple layers such that a first outermost layer defines the first side and a second outermost layer defines the second side. The first side of the substrate can directly engage the surface of the first-side portion including a filter die. The first side of the substrate can engage a mounting surface of the filter die to provide a gapless interconnect between the filter die and the first side of the substrate.

In some embodiments, the forming of the second-side portion can include implementing a plurality of pins on the second side of the substrate.

In some embodiments, the carrier can include a metal carrier.

In some embodiments, the carrier can be dimensioned to allow processing of an array of units each including a respective first-side portion, such that an array of packaged modules are manufactured while in an array format. In some embodiments, the method can further include singulating the array of packaged modules into a plurality of individual packaged modules.

In some embodiments, the forming or providing of the substrate can include the passive element being implemented as one or more features printed on one or more layers of the redistribution layers.

In some embodiments, the passive element can include an inductor, a capacitor or a resistor. The passive element can be configured to provide a radio-frequency functionality with respect to a filter die of the first-side portion. The radio-frequency functionality can include a matching functionality. The passive element can be configured to provide the radio-frequency functionality with a desired quality factor.

In some embodiments, the passive element can be implemented on a selected layer of the redistribution layers. The selected layer can include a layer at or closest to the first side of the substrate. The selected layer can include a layer adjacent to a layer associated with the first side of the substrate.

In some embodiments, the providing or forming of the substrate can further include implementing another passive element as part of the redistribution layers. The passive element and the other passive element can be implemented on a common layer. The passive element and the other passive element can be implemented on different layers.

In some embodiments, the passive element can be implemented to provide a lateral footprint that at least partially overlaps with a lateral footprint of a filter die of the first-side portion to allow reduction of lateral dimensions of the packaged module.

In some embodiments, the first-side portion can include an acoustic wave filter die. In some embodiments, the acoustic wave filter die can include a surface acoustic wave (SAW) filter, a bulk acoustic wave (BAW) filter, or a multilayer piezoelectric substrate (MPS) filter.

In some embodiments, the first-side portion can further include another acoustic wave filter die. The acoustic wave filter die and the other acoustic wave filter die can be implemented as same type of acoustic wave filter device. The acoustic wave filter die and the other acoustic wave filter die can be implemented as different types of acoustic wave filter devices.

According to some implementations, the present disclosure relates to a method for manufacturing packaged modules. The method includes providing a carrier and providing or forming a substrate having first and second sides and redistribution layers on the carrier, such that the redistribution layers include a passive element, and such that the second side engages the carrier. The method further includes forming a first-side portion of a module on the first side of the substrate, and removing the carrier from the second side of the substrate. The method further includes forming a second-side portion of the module on the second side of the substrate.

In some embodiments, the forming of the first-side portion can include attaching a filter die on the first side of the substrate, and forming a mold structure over the first side of the substrate to at least partially encapsulate the filter die.

In some embodiments, the removing of the carrier from the second side of the substrate can include a debonding process.

In some embodiments, the substrate can be a pre-fabricated substrate having multiple layers such that a first outermost layer defines the first side and a second outermost layer defines the second side. The first side of the substrate can directly engage the surface of the first-side portion. The first side of the substrate can engage a mounting surface of a filter die of the first-side portion to provide a gapless interconnect between the filter die and the first side of the substrate.

In some embodiments, the substrate can be formed over the surface of the carrier. The forming of the substrate can include forming multiple layers such that a first outermost layer defines the first side and a second outermost layer defines the second side. The first side of the substrate can directly engage the surface of the first-side portion including a filter die. The first side of the substrate can engage a mounting surface of the filter die to provide a gapless interconnect between the filter die and the first side of the substrate.

In some embodiments, the forming of the second-side portion can include implementing a plurality of pins on the second side of the substrate.

In some embodiments, the carrier can include a metal carrier.

In some embodiments, the carrier can be dimensioned to allow processing of an array of units each including a respective substrate and a respective first-side portion, such that an array of packaged modules are manufactured while in an array format. In some embodiments, the method can further include singulating the array of packaged modules into a plurality of individual packaged modules.

In some embodiments, the forming or providing of the substrate can include the passive element being implemented as one or more features printed on one or more layers of the redistribution layers.

In some embodiments, the passive element can include an inductor, a capacitor or a resistor. The passive element can be configured to provide a radio-frequency functionality with respect to a filter die of the first-side portion. The radio-frequency functionality can include a matching functionality. The passive element can be configured to provide the radio-frequency functionality with a desired quality factor.

In some embodiments, the passive element can be implemented on a selected layer of the redistribution layers. The selected layer can include a layer at or closest to the first side of the substrate. The selected layer can include a layer adjacent to a layer associated with the first side of the substrate.

In some embodiments, the providing or forming of the substrate can further include implementing another passive element as part of the redistribution layers. The passive element and the other passive element can be implemented on a common layer. The passive element and the other passive element can be implemented on different layers.

In some embodiments, the passive element can be implemented to provide a lateral footprint that at least partially overlaps with a lateral footprint of a filter die of the first-side portion to allow reduction of lateral dimensions of the packaged module.

In some embodiments, the first-side portion can include an acoustic wave filter die. The acoustic wave filter die can include a surface acoustic wave (SAW) filter, a bulk acoustic wave (BAW) filter, or a multilayer piezoelectric substrate (MPS) filter.

In some embodiments, the first-side portion can further include another acoustic wave filter die. The acoustic wave filter die and the other acoustic wave filter die can be implemented as same type of acoustic wave filter device. The acoustic wave filter die and the other acoustic wave filter die can be implemented as different types of acoustic wave filter devices.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1 depicts a packaged module having a packaging substrate, an RF die implemented on the substrate, and a plurality of pins implemented on the substrate to provide mounting and electrical connection functionalities when mounted on a circuit board.

FIG. 2 shows that in some embodiments, the RF die of FIG. 1 can include one or more acoustic wave devices.

FIGS. 3A to 31 depict block diagrams of non-limiting examples of packaged modules each having acoustic wave based filter(s), integrated passive element(s) and connection/mounting pins.

FIGS. 4A to 41 depict plan views of the packaged modules of FIGS. 3A to 31, respectively.

FIG. 5 shows that in some embodiments, a packaged module can include a filtering functionality between an input associated with a pin and an output associated with a pin.

FIG. 6 shows that in some embodiments, a packaged module can include filtering functionalities between a plurality of inputs associated with pins and a plurality of outputs associated with pins.

FIG. 7 shows that in some embodiments, a packaged module can include filtering functionalities between a plurality of nodes associated with pins and a common node associated with a pin.

FIG. 8 shows a side sectional view of a packaging substrate that can be utilized to form a packaged module.

FIGS. 9A to 9G show non-limiting examples of passive elements implemented in packaging substrates of respective packaged modules.

FIG. 10A shows examples of a passive element implemented as an inductor.

FIG. 10B shows a circuit representation of each example inductor of FIG. 10A.

FIG. 11A shows examples of a passive element implemented as a resistor.

FIG. 11B shows a circuit representation of each example resistor of FIG. 11A.

FIG. 12A shows an example of a passive element implemented as a capacitor.

FIG. 12B shows a circuit representation of the example capacitor of FIG. 12A.

FIGS. 13A and 13B show that packaged modules having one or more features as described herein can be implemented with different types of mounting/connection pins on a mounting side of an RDL substrate.

FIG. 13C shows that in some embodiments, a packaged module having one or more features as described herein can include more than one acoustic wave filter provided on a non-mounting side of an RDL substrate.

FIGS. 14A to 14F show various stages of a process that can be utilized to fabricate a packaged module having one or more features as described herein.

FIG. 14G shows the packaged module of FIG. 14F in an inverted orientation.

FIG. 14H shows that in some embodiments, a mold structure of a packaged module can be thinned to provide a new thickness dimension.

FIG. 14I shows that in some embodiments, the mold structure of the packaged module of FIG. 14H can be thinned further to provide a new thickness dimension.

FIG. 15 shows a packaged module that is similar to the module of FIG. 13A.

FIGS. 16A to 16F show various stages of a process where an RDL substrate is provided or constructed on a carrier before building of any-side portion of a module.

FIGS. 17A to 17C show example stages of fabrication where multiple units are processed while in an array format and then singulated to provide multiple packaged units.

FIGS. 18A to 18C show that in some embodiments, a rectangular shaped carrier can be utilized to fabricate an array of modules having one or more features as described herein.

FIG. 19 shows that in some embodiments, one or more features of the present disclosure can be implemented in a module packaging system.

### DETAILED DESCRIPTION OF SOME EMBODIMENTS

The headings provided herein, if any, are for convenience only and do not necessarily affect the scope or meaning of the claimed invention.

In many applications, sizes of packaged modules are shrinking; thus, it is desirable to provide reduced footprints in packaged modules including modules that have radio-frequency (RF) filters such as filters based on acoustic wave devices. In some embodiments, a packaged module can include one or more of such filters and one or more passive elements for supporting (e.g., matching) such filter(s).

FIG. 1 depicts a packaged module 100 having a packaging substrate 102, an RF die 110 implemented on the substrate 102, and a plurality of pins 142 implemented on the substrate 102 (e.g., on a side opposite from the side with the die 110) to provide mounting and electrical connection functionalities when mounted on a circuit board. In some embodiments, one or more passive elements 140 can be implemented on and/or within the substrate 102. Examples related to the RF die 110, the passive element(s) 140 and the pins 142 are provided herein in greater detail.

In FIG. 1, the packaged module 100 is shown to have lateral dimensions d1 by d2. In some embodiments, one or more features as described herein can allow such dimensions to be reduced while providing various functionalities associated with the RF die 110 and passive element(s) 140.

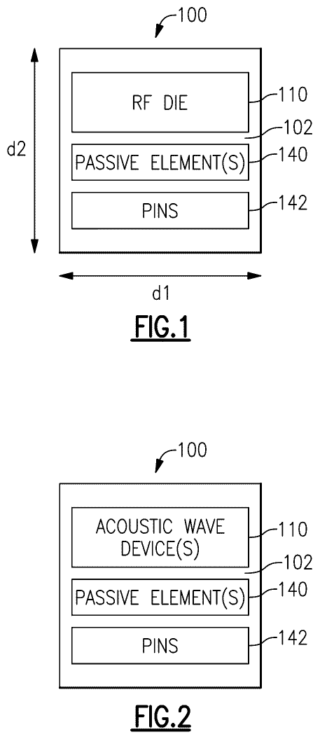

FIG. 2 shows that in some embodiments, the RF die 110 of FIG. 1 can include acoustic wave device(s). Examples of such acoustic wave devices are provided herein in greater detail.

In some embodiments, the packaging substrate 102 of FIG. 2 can be configured to provide wafer level fan out functionality utilizing redistribution layers (RDL), with one or more of such redistribution layers including respective passive element(s) integrated therein. By integrating such passive element(s) in a three-dimensional manner in the packaging substrate 102, more flexibility in footprint dimensions (e.g., d1 and d2 in FIG. 1) of the packaged module 100 can be provided. For example, either or both of the footprint dimensions d1 and d2 can be reduced.

It is noted that in some embodiments, a packaged module having one or more features as described herein can include a mold structure implemented over an RDL or RDL-based packaging substrate to substantially encapsulate one or more die mounted thereon. In some embodiments, such a mold structure can be formed using a low pressure liquid molding technique. It is noted that in embodiments where a die being encapsulated is an acoustic wave device, such a molding technique can provide a significant impact on some or all of size, performance and reliability of the acoustic wave device.

It is noted that while various examples are described herein in the context of RF filter die, one or more features of the present disclosure can also be implemented in other types of die where packaging configuration includes fan out functionality.

In the example context where a die of a packaged module is an RF die such as an acoustic wave based filter, a wafer level fan out packaging configuration with one or more integrated passive elements (e.g., one or more inductors) as described herein can result in the packaged module having lateral dimensions that are similar to or only slightly larger than a conventional packaged module having a similar RF die but without integrated passive element(s).

In some embodiments, some or all of integrated passive element(s) as described herein can be implemented to provide desired quality factor(s) such as high quality factor(s). Thus, implementation of such integrated passive element(s) in a packaged module can provide the foregoing size advantage as well as desired performance characteristics.

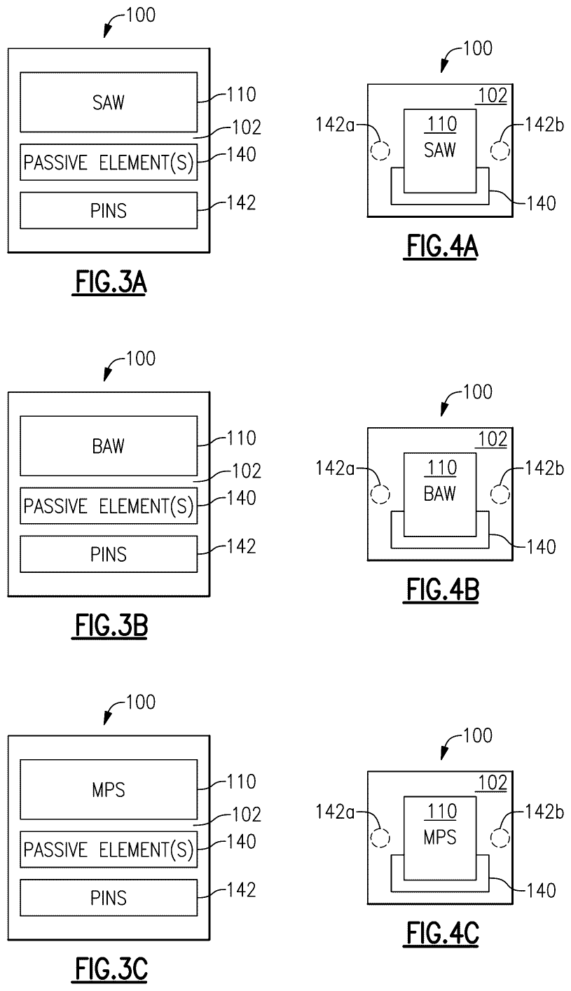

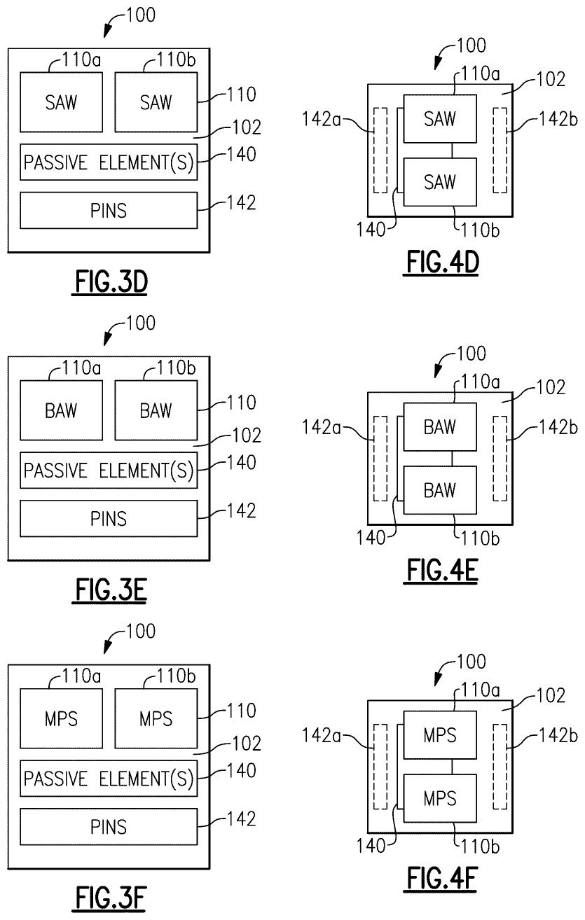

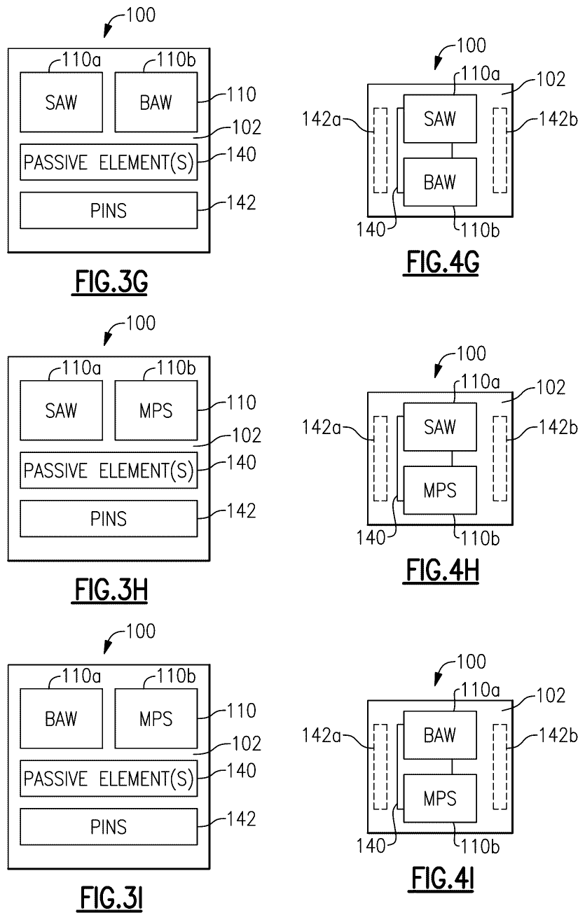

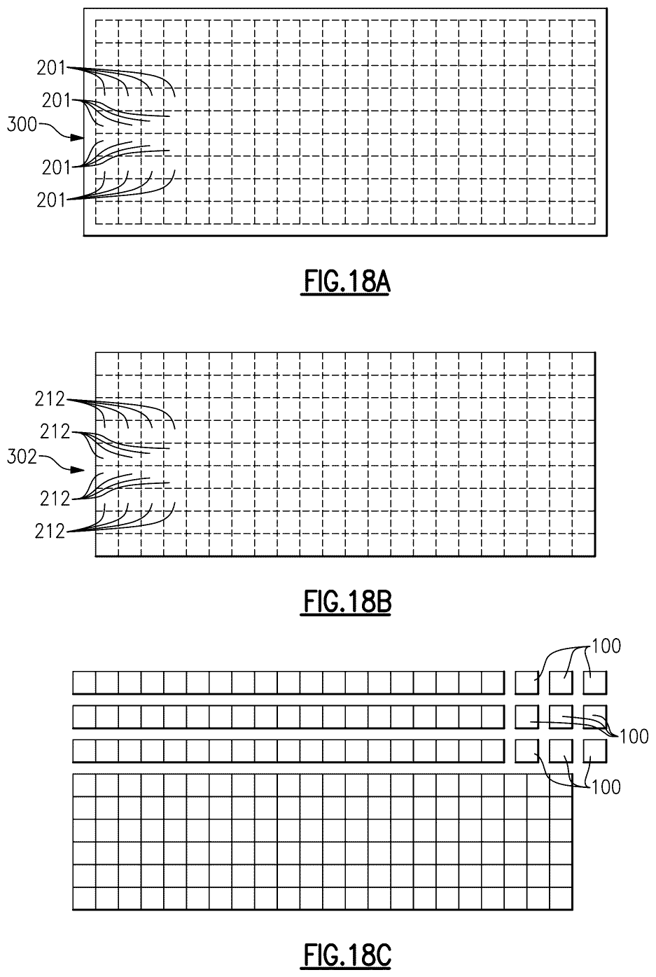

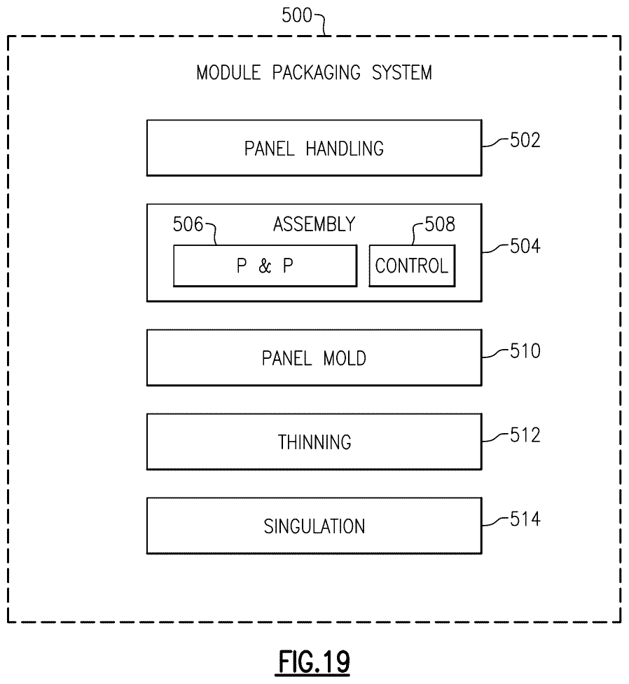

FIGS. 3A to 31 depict block diagrams of non-limiting examples packaged modules each having acoustic wave based filter(s), integrated passive element(s) and connection/mounting pins. FIGS. 4A to 41 depict plan views of the packaged modules of FIGS. 3A to 31, respectively. It is noted that in each of FIGS. 4A to 41, one or more integrated passive elements is/are collectively indicated as 140, and such passive element(s) is/are shown to be underneath respective acoustic wave based filter(s) when viewed as shown. It will be understood that lateral area occupied by the passive element(s) 140 may or may not overlap with lateral area occupied by the respective acoustic wave based filter(s).

FIG. 3A shows that in some embodiments, a packaged module 100 can include a packaging substrate 102 that includes one or more integrated passive elements 140. In some embodiments, the packaging substrate 102 can include redistribution layers (RDL), with one or more of such redistribution layers including respective passive element(s) 140 integrated therein. The packaged module 100 is shown to further include a surface acoustic wave (SAW) filter 110 and a group of pins 142 implemented with respect to the packaging substrate 102.

FIG. 4A shows that in some embodiments, the packaged module 100 of FIG. 3A can be implemented such that the one or more passive elements 140 is/are on and/or within the packaging substrate 102, the SAW filter 110 is mounted on a first side of the packaging substrate 102, and the group of pins (e.g., 142a, 142b) is implemented on a second side, opposite from the first side, of the packaging substrate 102. In some embodiments, the second side of the packaging substrate 102 can be the mounting side of the packaged module 100, and the first side of the packaging substrate 102 can be the non-mounting side of the packaged module 100.

In some embodiments, at least one the one or more passive elements 140 can be implemented on a respective redistribution layer that is closer to the non-mounting side (where the SAW filter 110 is positioned) than to the mounting side of the packaging substrate 102. For example, a passive element can be implemented on an upper redistribution layer immediately below the SAW filter 110, or the next layer underneath the upper redistribution layer. It will be understood that in some embodiments, a passive element 140 as described herein can be implemented in any layer of the packaging substrate.

FIG. 3B shows that in some embodiments, a packaged module 100 can include a packaging substrate 102 that includes one or more integrated passive elements 140. In some embodiments, the packaging substrate 102 can include redistribution layers (RDL), with one or more of such redistribution layers including respective passive element(s) 140 integrated therein. The packaged module 100 is shown to further include a bulk acoustic wave (BAW) filter 110 and a group of pins 142 implemented with respect to the packaging substrate 102.

FIG. 4B shows that in some embodiments, the packaged module 100 of FIG. 3B can be implemented such that the one or more passive elements 140 is/are on and/or within the packaging substrate 102, the BAW filter 110 is mounted on a first side of the packaging substrate 102, and the group of pins (e.g., 142a, 142b) is implemented on a second side, opposite from the first side, of the packaging substrate 102. In some embodiments, the second side of the packaging substrate 102 can be the mounting side of the packaged module 100, and the first side of the packaging substrate 102 can be the non-mounting side of the packaged module 100.

In some embodiments, at least one the one or more passive elements 140 can be implemented on a respective redistribution layer that is closer to the non-mounting side (where the BAW filter 110 is positioned) than to the mounting side of the packaging substrate 102. For example, a passive element can be implemented on an upper redistribution layer immediately below the BAW filter 110, or the next layer underneath the upper redistribution layer. It will be understood that in some embodiments, a passive element 140 as described herein can be implemented in any layer of the packaging substrate.

FIG. 3C shows that in some embodiments, a packaged module 100 can include a packaging substrate 102 that includes one or more integrated passive elements 140. In some embodiments, the packaging substrate 102 can include redistribution layers (RDL), with one or more of such redistribution layers including respective passive element(s) 140 integrated therein. The packaged module 100 is shown to further include a multilayer piezoelectric substrate (MPS) filter 110 and a group of pins 142 implemented with respect to the packaging substrate 102.

FIG. 4C shows that in some embodiments, the packaged module 100 of FIG. 3C can be implemented such that the one or more passive elements 140 is/are on and/or within the packaging substrate 102, the MPS filter 110 is mounted on a first side of the packaging substrate 102, and the group of pins (e.g., 142a, 142b) is implemented on a second side, opposite from the first side, of the packaging substrate 102. In some embodiments, the second side of the packaging substrate 102 can be the mounting side of the packaged module 100, and the first side of the packaging substrate 102 can be the non-mounting side of the packaged module 100.

In some embodiments, at least one the one or more passive elements 140 can be implemented on a respective redistribution layer that is closer to the non-mounting side (where the MPS filter 110 is positioned) than to the mounting side of the packaging substrate 102. For example, a passive element can be implemented on an upper redistribution layer immediately below the MPS filter 110, or the next layer underneath the upper redistribution layer. It will be understood that in some embodiments, a passive element 140 as described herein can be implemented in any layer of the packaging substrate.

In some embodiments, a packaged module having one or more features as described herein can include a plurality of acoustic wave filters. Such acoustic wave filters can be of same type, different types, or some combination thereof. For example, FIGS. 3D to 3F show examples where two same-type acoustic wave filters are utilized, and FIGS. 3G to 31 show examples where two different types of acoustic wave filters are utilized. Although the foregoing examples are in the context of two acoustic wave filters, it will be understood that more than two acoustic wave filters (e.g., same type, different types, or some combination thereof) can also be utilized in a packaged module as described herein.

FIG. 3D shows that in some embodiments, a packaged module 100 can include a packaging substrate 102 that includes one or more integrated passive elements 140. In some embodiments, the packaging substrate 102 can include redistribution layers (RDL), with one or more of such redistribution layers including respective passive element(s) 140 integrated therein. The packaged module 100 is shown to further include first and second SAW filters 110a, 110b and a group of pins 142 implemented with respect to the packaging substrate 102.

FIG. 4D shows that in some embodiments, the packaged module 100 of FIG. 3D can be implemented such that the one or more passive elements 140 is/are on and/or within the packaging substrate 102, the SAW filters 110a, 110b are mounted on a first side of the packaging substrate 102, and the group of pins (e.g., 142a, 142b) is implemented on a second side, opposite from the first side, of the packaging substrate 102. In some embodiments, the second side of the packaging substrate 102 can be the mounting side of the packaged module 100, and the first side of the packaging substrate 102 can be the non-mounting side of the packaged module 100.

In some embodiments, at least one the one or more passive elements 140 can be implemented on a respective redistribution layer that is closer to the non-mounting side (where the SAW filters 110a, 110b are positioned) than to the mounting side of the packaging substrate 102. For example, a passive element can be implemented on an upper redistribution layer immediately below the SAW filters 110a, 110b, or the next layer underneath the upper redistribution layer. It will be understood that in some embodiments, a passive element 140 as described herein can be implemented in any layer of the packaging substrate.

FIG. 3E shows that in some embodiments, a packaged module 100 can include a packaging substrate 102 that includes one or more integrated passive elements 140. In some embodiments, the packaging substrate 102 can include redistribution layers (RDL), with one or more of such redistribution layers including respective passive element(s) 140 integrated therein. The packaged module 100 is shown to further include first and second BAW filters 110a, 110b and a group of pins 142 implemented with respect to the packaging substrate 102.

FIG. 4E shows that in some embodiments, the packaged module 100 of FIG. 3E can be implemented such that the one or more passive elements 140 is/are on and/or within the packaging substrate 102, the BAW filters 110a, 110b are mounted on a first side of the packaging substrate 102, and the group of pins (e.g., 142a, 142b) is implemented on a second side, opposite from the first side, of the packaging substrate 102. In some embodiments, the second side of the packaging substrate 102 can be the mounting side of the packaged module 100, and the first side of the packaging substrate 102 can be the non-mounting side of the packaged module 100.

In some embodiments, at least one the one or more passive elements 140 can be implemented on a respective redistribution layer that is closer to the non-mounting side (where the BAW filters 110a, 110b are positioned) than to the mounting side of the packaging substrate 102. For example, a passive element can be implemented on an upper redistribution layer immediately below the BAW filters 110a, 110b, or the next layer underneath the upper redistribution layer. It will be understood that in some embodiments, a passive element 140 as described herein can be implemented in any layer of the packaging substrate.

FIG. 3F shows that in some embodiments, a packaged module 100 can include a packaging substrate 102 that includes one or more integrated passive elements 140. In some embodiments, the packaging substrate 102 can include redistribution layers (RDL), with one or more of such redistribution layers including respective passive element(s) 140 integrated therein. The packaged module 100 is shown to further include first and second MPS filters 110a, 110b and a group of pins 142 implemented with respect to the packaging substrate 102.

FIG. 4F shows that in some embodiments, the packaged module 100 of FIG. 3F can be implemented such that the one or more passive elements 140 is/are on and/or within the packaging substrate 102, the MPS filters 110a, 110b are mounted on a first side of the packaging substrate 102, and the group of pins (e.g., 142a, 142b) is implemented on a second side, opposite from the first side, of the packaging substrate 102. In some embodiments, the second side of the packaging substrate 102 can be the mounting side of the packaged module 100, and the first side of the packaging substrate 102 can be the non-mounting side of the packaged module 100.

In some embodiments, at least one the one or more passive elements 140 can be implemented on a respective redistribution layer that is closer to the non-mounting side (where the MPS filters 110a, 110b are positioned) than to the mounting side of the packaging substrate 102. For example, a passive element can be implemented on an upper redistribution layer immediately below the MPS filters 110a, 110b, or the next layer underneath the upper redistribution layer. It will be understood that in some embodiments, a passive element 140 as described herein can be implemented in any layer of the packaging substrate.

FIG. 3G shows that in some embodiments, a packaged module 100 can include a packaging substrate 102 that includes one or more integrated passive elements 140. In some embodiments, the packaging substrate 102 can include redistribution layers (RDL), with one or more of such redistribution layers including respective passive element(s) 140 integrated therein. The packaged module 100 is shown to further include a SAW filter 110a, a BAW filter 110b and a group of pins 142 implemented with respect to the packaging substrate 102.

FIG. 4G shows that in some embodiments, the packaged module 100 of FIG. 3G can be implemented such that the one or more passive elements 140 is/are on and/or within the packaging substrate 102, the SAW and BAW filters 110a, 110b are mounted on a first side of the packaging substrate 102, and the group of pins (e.g., 142a, 142b) is implemented on a second side, opposite from the first side, of the packaging substrate 102. In some embodiments, the second side of the packaging substrate 102 can be the mounting side of the packaged module 100, and the first side of the packaging substrate 102 can be the non-mounting side of the packaged module 100.

In some embodiments, at least one the one or more passive elements 140 can be implemented on a respective redistribution layer that is closer to the non-mounting side (where the SAW and BAW filters 110a, 110b are positioned) than to the mounting side of the packaging substrate 102. For example, a passive element can be implemented on an upper redistribution layer immediately below the SAW and BAW filters 110a, 110b, or the next layer underneath the upper redistribution layer. It will be understood that in some embodiments, a passive element 140 as described herein can be implemented in any layer of the packaging substrate.

FIG. 3H shows that in some embodiments, a packaged module 100 can include a packaging substrate 102 that includes one or more integrated passive elements 140. In some embodiments, the packaging substrate 102 can include redistribution layers (RDL), with one or more of such redistribution layers including respective passive element(s) 140 integrated therein. The packaged module 100 is shown to further include a SAW filter 110a, an MPS filter 110b and a group of pins 142 implemented with respect to the packaging substrate 102.

FIG. 4H shows that in some embodiments, the packaged module 100 of FIG. 3H can be implemented such that the one or more passive elements 140 is/are on and/or within the packaging substrate 102, the SAW and MPS filters 110a, 110b are mounted on a first side of the packaging substrate 102, and the group of pins (e.g., 142a, 142b) is implemented on a second side, opposite from the first side, of the packaging substrate 102. In some embodiments, the second side of the packaging substrate 102 can be the mounting side of the packaged module 100, and the first side of the packaging substrate 102 can be the non-mounting side of the packaged module 100.

In some embodiments, at least one the one or more passive elements 140 can be implemented on a respective redistribution layer that is closer to the non-mounting side (where the SAW and MPS filters 110a, 110b are positioned) than to the mounting side of the packaging substrate 102. For example, a passive element can be implemented on an upper redistribution layer immediately below the SAW and MPS filters 110a, 110b, or the next layer underneath the upper redistribution layer. It will be understood that in some embodiments, a passive element 140 as described herein can be implemented in any layer of the packaging substrate.

FIG. 31 shows that in some embodiments, a packaged module 100 can include a packaging substrate 102 that includes one or more integrated passive elements 140. In some embodiments, the packaging substrate 102 can include redistribution layers (RDL), with one or more of such redistribution layers including respective passive element(s) 140 integrated therein. The packaged module 100 is shown to further include a BAW filter 110a, an MPS filter 110b and a group of pins 142 implemented with respect to the packaging substrate 102.

FIG. 41 shows that in some embodiments, the packaged module 100 of FIG. 31 can be implemented such that the one or more passive elements 140 is/are on and/or within the packaging substrate 102, the BAW and MPS filters 110a, 110b are mounted on a first side of the packaging substrate 102, and the group of pins (e.g., 142a, 142b) is implemented on a second side, opposite from the first side, of the packaging substrate 102. In some embodiments, the second side of the packaging substrate 102 can be the mounting side of the packaged module 100, and the first side of the packaging substrate 102 can be the non-mounting side of the packaged module 100.

In some embodiments, at least one the one or more passive elements 140 can be implemented on a respective redistribution layer that is closer to the non-mounting side (where the BAW and MPS filters 110a, 110b are positioned) than to the mounting side of the packaging substrate 102. For example, a passive element can be implemented on an upper redistribution layer immediately below the BAW and MPS filters 110a, 110b, or the next layer underneath the upper redistribution layer. It will be understood that in some embodiments, a passive element 140 as described herein can be implemented in any layer of the packaging substrate.

As described herein, a packaged module having one or more acoustic wave filters implemented on a packaging substrate with fan out functionality and one or more passive elements implemented as part(s) of the packaging substrate can allow the packaged module to provide high-performance RF filtering functionality in a reduced size format. FIGS. 5 to 7 show non-limiting examples of RF filtering functionalities that can be provided with a packaged module having one or more features as described herein.

For example, FIG. 5 shows that in some embodiments, a packaged module 100 can include a filtering functionality between an input associated with a pin 142a and an output associated with a pin 142b. In such an example, a filter circuit implemented as one or more acoustic wave filter die 110 can be provided to be electrically between the input and output pins 142a, 142b, and one or more passive elements 140 can be implemented relative to the filter circuit 110 to provide, for example, matching functionality.

In the example of FIG. 5, passive element(s) 140 is/are depicted as being implemented on the output sides of the filter circuit 110; however, it will be understood that passive element(s) as described herein can be implemented on an input side and/or on an output side of a filter circuit.

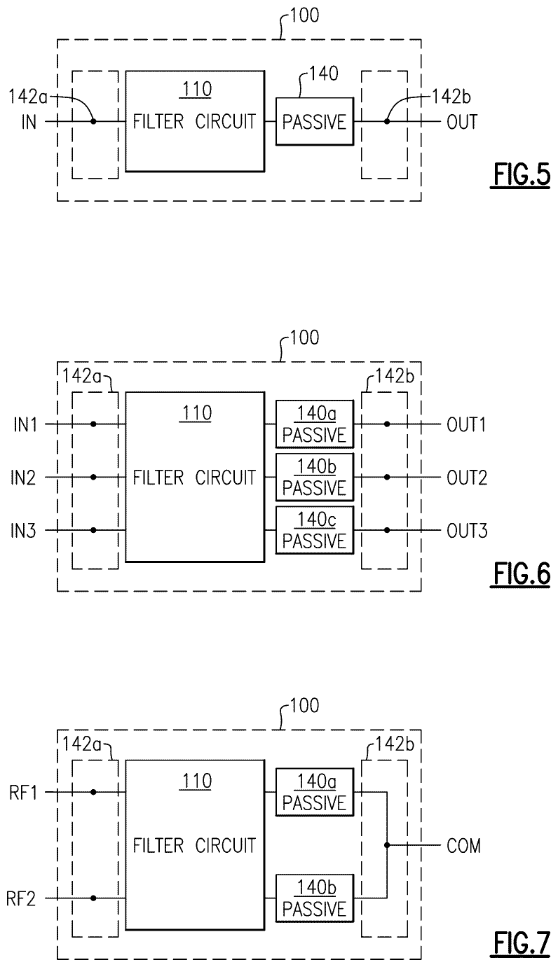

In another example, FIG. 6 shows that in some embodiments, a packaged module 100 can include filtering functionalities between a plurality of inputs associated with pins 142a and a plurality of outputs associated with pins 142b. In such an example, a filter circuit implemented as one or more acoustic wave filter die 110 can be provided to be electrically between the input pins 142a and output pins 142b, and one or more passive elements 140 can be implemented relative to each of at least some of the filtering paths to provide, for example, matching functionality.

For example, and referring to FIG. 6, one or more passive elements can be implemented for each of the filtering paths. In such an example, one or more passive elements 140a can be implemented for a first filtering path between the first input (In1) and the first output (Out1); one or more passive elements 140b can be implemented for a second filtering path between the second input (In2) and the second output (Out2); and one or more passive elements 140c can be implemented for a third filtering path between the third input (In3) and the third output (Out3).

In the example of FIG. 6, passive elements 140a, 140b, 140c are depicted as being implemented on the output sides of the filter circuit 110; however, it will be understood that passive element(s) as described herein can be implemented on an input side and/or on an output side of a filter circuit.

In yet another example, FIG. 7 shows that in some embodiments, a packaged module 100 can include filtering functionalities between a plurality of nodes associated with pins 142a and a common node associated with a pin 142b. In such an example, a filter circuit implemented as one or more acoustic wave filter die 110 can be provided to be electrically between the pins 142a and the pin 142b, and one or more passive elements 140 can be implemented relative to each of at least some of the filtering paths to provide, for example, matching functionality.

For example, and referring to FIG. 7, one or more passive elements can be implemented for each of the filtering paths. In such an example, one or more passive elements 140a can be implemented for a first filtering path between the first node (RF1) and the common node (COM); and one or more passive elements 140b can be implemented for a second filtering path between the second node (RF2) and the common node (COM).

In the example of FIG. 7, passive elements 140a, 140b are depicted as being implemented on the common node (COM) sides of the filter circuit 110; however, it will be understood that passive element(s) as described herein can be implemented on RF node side and/or on a common node side of a filter circuit.

In some embodiments, the filtering architecture of the packaged module 100 can be implemented as a multiplexer configured to provide multiplexing/filtering functionality between a plurality of RF nodes and a common node. In some embodiments, the common node (COM) can be an input node, and the RF nodes (RF1, RF2) can be output nodes for the filter circuit 110. In some embodiments, the RF nodes (RF1, RF2) can be input nodes, and the common node (COM) can be an output node for the filter circuit 110.

Although the example multiplexing architecture of FIG. 7 shows two filtering paths (e.g., as a diplexer), it will be understood that more than two filtering paths can also be implemented in a packaged module as described herein.

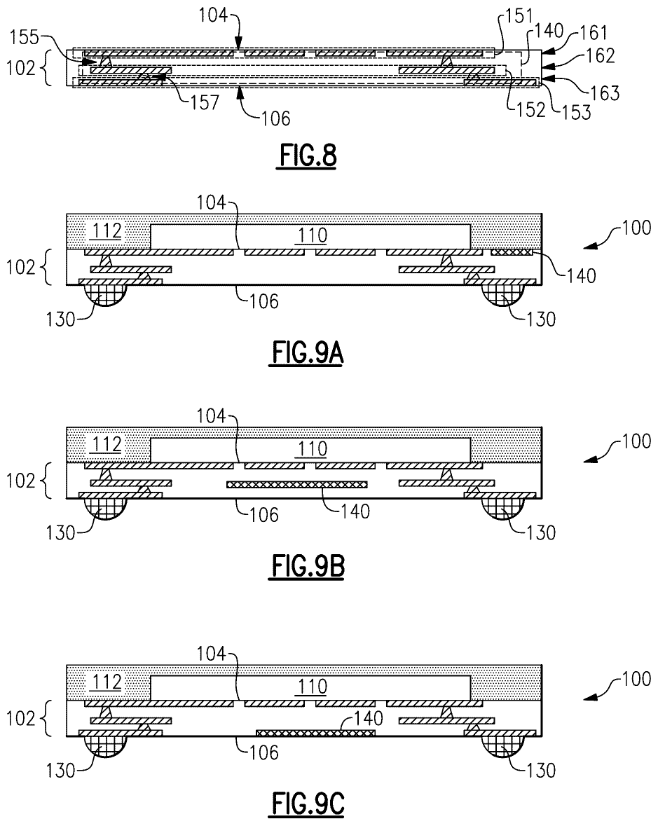

FIG. 8 shows a side sectional view of a packaging substrate 102 that can be utilized to form a packaged module. In some embodiments, such a packaging substrate can include a plurality of redistribution layers (RDL) that provide redistribution (e.g., fan out) of electrical connections between a die (e.g., acoustic wave filter die) on a first surface 104 of the packaging substrate 102 and mounting pins on a second surface 106 of the packaging substrate 102.

In the example of FIG. 8, a plurality of layers with conductive features are shown to provide electrical connections between the first surface 104 and the second surface 106 of the packaging substrate 102. More particularly, a group 151 of conductive features such as metal layers, traces and/or pads are shown to be part of a layer 161 of the packaging substrate 102, such that some or all of the group 151 of conductive features are exposed on the first surface 104 to allow mounting of a die thereon. Similarly, a group 153 of conductive features such as metal layers, traces and/or pads are shown to be part of a layer 163 of the packaging substrate 102, such that some or all of the group 153 of conductive features are exposed on the second surface 106 to allow implementation of connecting/mounting pins thereon.

In FIG. 8, another group 152 of conductive features such as metal layers, traces and/or pads are shown to be part of a layer 162 of the packaging substrate 102, such that the layer 162 is between the above-described layers 161 and 163. Accordingly, three groups of conductive features are provided in the example of FIG. 8. It will be understood that more or less groups of conductive features can be implemented in packaging substrates having one or more features as described herein.

In some embodiments, electrical connections between groups of conductive features can be provided by, for example, conductive vias and respective pads. In the example of FIG. 8, conductive vias 155 are shown to provide electrical connections between the groups of conductive features 151, 152. Similarly conductive vias 157 are shown to provide electrical connections between the groups of conductive features 152, 153.

Referring to the example of FIG. 8, it is noted that the packaging substrate 102 can include a plurality of protective layers such as polyimide layers implemented to support and protect some or all of conductive features associated with respective redistribution layers. In some embodiments, a polyimide layer can be implemented to be under and/or over a group of conductive features, and/or to be laterally adjacent a conductive feature of the group.

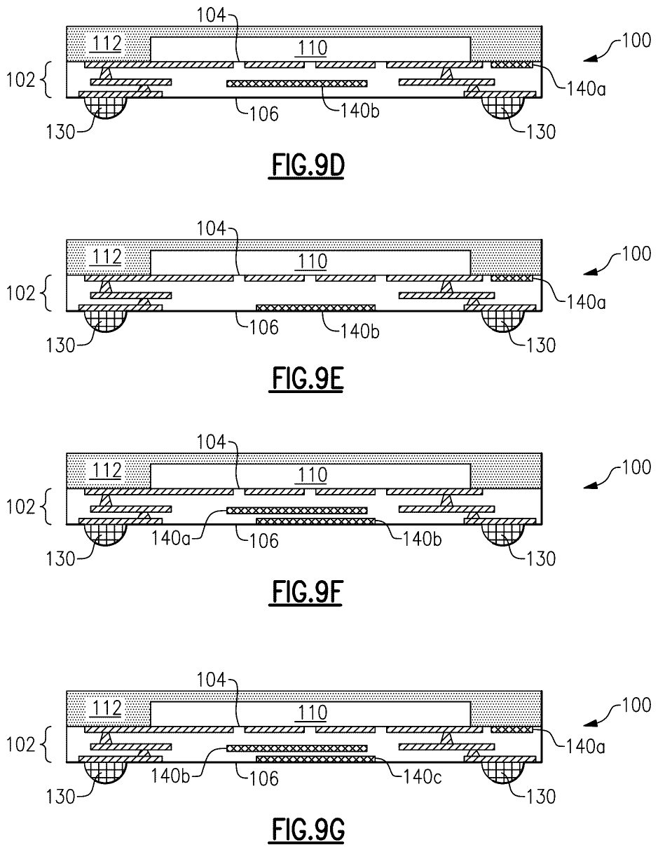

FIG. 8 shows that in some embodiments, the packaging substrate 102 can include one or more passive elements 140 implemented to be in respective layer(s) associated with one or more of the groups of conductive features. FIGS. 9A to 9G show non-limiting examples of such passive elements implemented in packaging substrates of respective packaged modules.

In the examples of FIGS. 9A to 9G, each packaged module 100 is depicted as including an acoustic wave filter die 110 implemented on a first side 104 of an RDL substrate 102, and ball-shaped structures (e.g., solder balls) as mounting/connection pins 130 implemented on a second side 106 of the RDL substrate 102. It will be understood that more than one acoustic wave filter die can be implemented on the first side 104 of the RDL substrate 102. Similarly, it will be understood that the pins 130 can be implemented as different type of mounting/connection structures.

FIGS. 9A to 9C show examples where an RDL substrate 102 includes a passive element 140 implemented with a group of conductive features. FIG. 9A shows an example where a passive element 140 is implemented with a group of conductive features generally in a layer at or closest to the first surface 104. FIG. 9B shows an example where a passive element 140 is implemented with a group of conductive features generally in a second layer from the first surface 104. FIG. 9C shows an example where a passive element 140 is implemented with a group of conductive features generally in a layer at or closest to the second surface 106.

It is noted that in the examples of FIGS. 9A to 9C, there are three layers with respective groups of conductive features, such that the configurations of FIGS. 9A and 9C correspond to a passive element 140 being implemented at or close to each of the first and second surfaces 104, 106, and the configuration of FIG. 9B corresponds to a passive element 140 being implemented at or close to an intermediate layer.

It will be understood that in some embodiments, an RDL substrate having one or more features as described herein can have less than or greater than the example three-layer configuration. For example, if there are two layers with respective conductive features, such layers can be implemented at or close to the first and second surfaces 104, 106. In another example, if there are more than three layers with respective conductive features, first and fourth layers can be implemented at or close to the first and second surfaces 104, 106, and second and third layers can be implemented as intermediate layers.

FIGS. 9D to 9F show examples where an RDL substrate 102 includes passive elements implemented with groups of conductive features associated with two different layers. FIG. 9D shows an example where a first passive element 140a is implemented with a group of conductive features generally in a layer at or closest to the first surface 104, and a second passive element 140b is implemented with a group of conductive features generally in a second layer from the first surface 104. FIG. 9E shows an example where a first passive element 140a is implemented with a group of conductive features generally in a layer at or closest to the first surface 104, and a second passive element 140b is implemented with a group of conductive features generally in a layer at or closest to the second surface 106. FIG. 9F shows an example where a first passive element 140a is implemented with a group of conductive features generally in an intermediate layer, and a second passive element 140b is implemented with a group of conductive features generally in a layer at or closest to the second surface 106.

FIG. 9G shows an example where an RDL substrate 102 includes passive elements implemented with groups of conductive features associated with all layers. For example, and in the context of the three layers of conductive features, FIG. 9G shows a configuration where a first passive element 140a is implemented with a group of conductive features generally in a layer at or closest to the first surface 104, a second passive element 140b is implemented with a group of conductive features generally in an intermediate layer, and a third passive element 140c is implemented with a group of conductive features generally in a layer at or closest to the second surface 106.

In some embodiments, a passive element implemented as part of an RDL substrate can include any circuit element that affects a signal in a circuit in a passive manner. Such a passive element can include, for example, an inductor, a resistor, a capacitor, or some combination thereof.

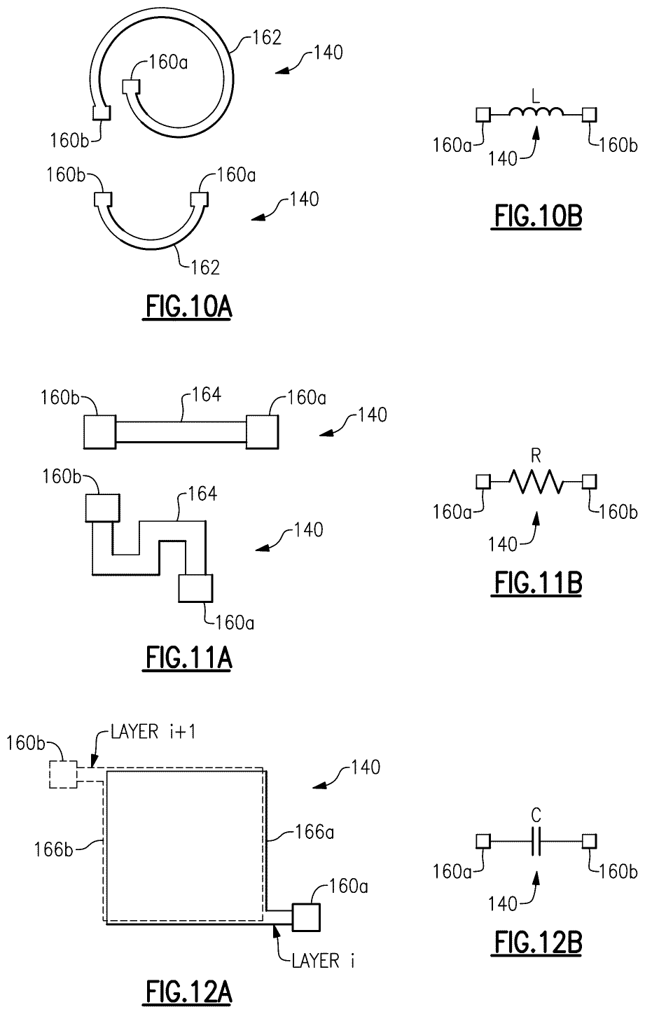

In some embodiments, the foregoing passive element can be formed on a layer of an RDL substrate by process suitable for fabrication of the RDL process. For example, FIG. 10A shows two examples of a passive element 140 implemented as an inductor. In one example, a metal trace 162 is shown to form at least one winding between end nodes 160a, 160b. In another example, a metal trace 162 is shown to form a partial winding between end nodes 160a, 160b. FIG. 10B shows a circuit representation of the inductor 140 of FIG. 10A between the nodes 160a, 160b.

In some embodiments, the foregoing metal traces and end nodes can be formed in a manner similar to formation of conductive features such as metal traces. It will be understood that while the foregoing inductor examples are depicted as having curved traces, an inductor can have other shapes to provide a desired inductance between first and second locations of a formed conductive path.

In another example, FIG. 11A shows two examples of a passive element 140 implemented as a resistor. In one example, a straight resistive path 164 is shown to be provided between end nodes 160a, 160b. In another example, a resistive path 164 with bends is shown to be provided between end nodes 160a, 160b. FIG. 11B shows a circuit representation of the resistor 140 of FIG. 11A between the nodes 160a, 160b.

In some embodiments, the foregoing end nodes can be formed in a manner similar to formation of conductive features such as metal traces, and resistive paths can be formed by patterning a layer of resistive material between the end nodes. It will be understood that a resistor can have other shapes to provide a desired resistance between first and second locations.

In yet another example, FIG. 12A shows an example of a passive element 140 implemented as a capacitor. In some embodiments, such a capacitor can be formed by first and second conductive planes 166a, 166b separated by a dielectric material with the first and second conductive planes 166a, 166b being electrically connected to respective nodes 160a, 160b. FIG. 12B shows a circuit representation of the capacitor 140 of FIG. 12A between the nodes 160a, 160b.

In some embodiments, the foregoing conductive planes 166a, 166b and nodes 160a, 160b can be formed in a manner similar to formation of conductive features such as metal traces.

In some embodiments, the separation between the first and second conductive planes 166a, 166b can be provided by the conductive planes being formed in different layers of conductive features. For example, the first conductive plane 166a on layer i, and the second conductive plane 166b on layer i+1, such that the two conductive planes are separated by, for example, a polyimide layer therebetween.

In some embodiments, the first and second conductive planes 166a, 166b can be provided by the conductive planes being formed on the same given layer of conductive features of the respective RDL substrate. In such an example, the two conductive planes can be separated by a dielectric material.

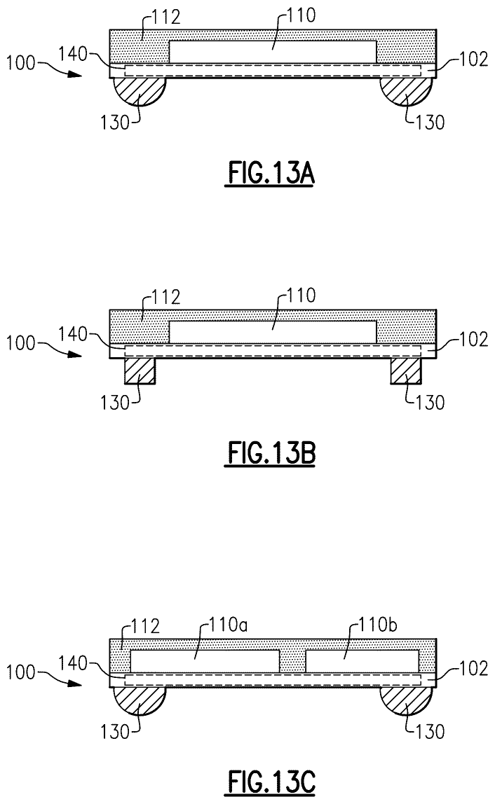

FIGS. 13A and 13B show that packaged modules having one or more features as described herein can be implemented with different types of mounting/connection pins on a mounting side of an RDL substrate. For example, FIG. 13A shows that in some embodiments, a plurality of mounting/connection pins are shown to be implemented as ball-shaped structures 130 (e.g., solder balls) on the mounting side of an RDL substrate 102. As described herein, such an RDL substrate can include one or more passive elements 140, and an acoustic wave filter die 110 and a mold structure 112 can be provided on the non-mounting side of the RDL substrate 102.

In another example, FIG. 13B shows that in some embodiments, a plurality of mounting/connection pins are shown to be implemented as metal post structures 130 (e.g., copper posts) on the mounting side of an RDL substrate 102. As described herein, such an RDL substrate can include one or more passive elements 140, and an acoustic wave filter die 110 and a mold structure 112 can be provided on the non-mounting side of the RDL substrate 102.

FIG. 13C shows that in some embodiments, a packaged module having one or more features as described herein can include more than one acoustic wave filter provided on a non-mounting side of an RDL substrate. For example, in FIG. 13C, first and second acoustic wave filter die 110a, 110b are shown to be provided on a non-mounting side of an RDL substrate 102, and a plurality of mounting/connection pins 130 are shown to be provided on a mounting side of the RDL substrate 102. As described herein, such an RDL substrate can include one or more passive elements 140.

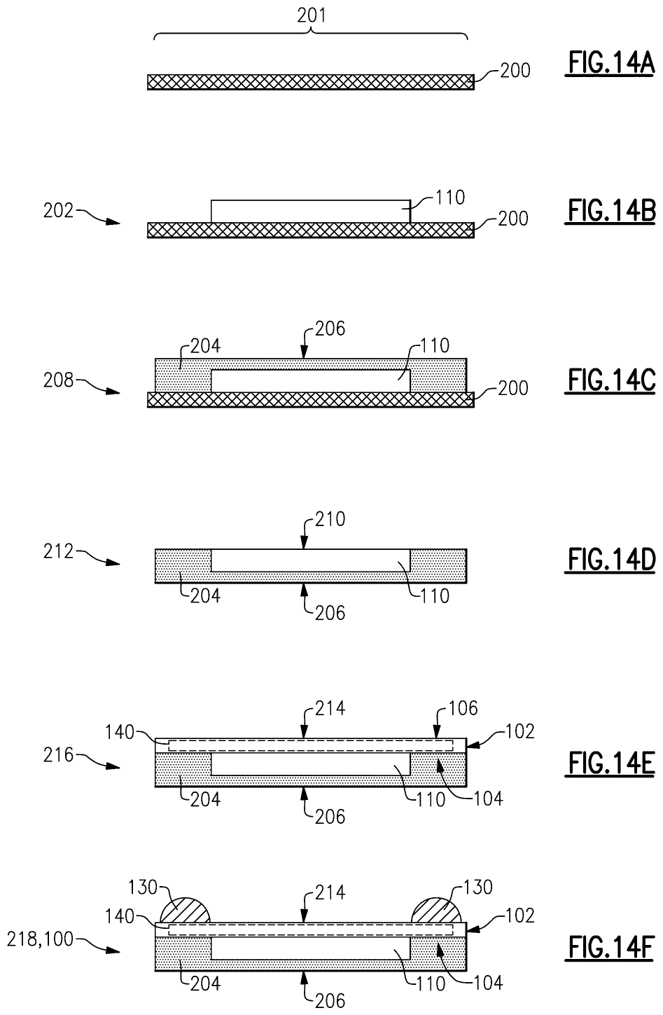

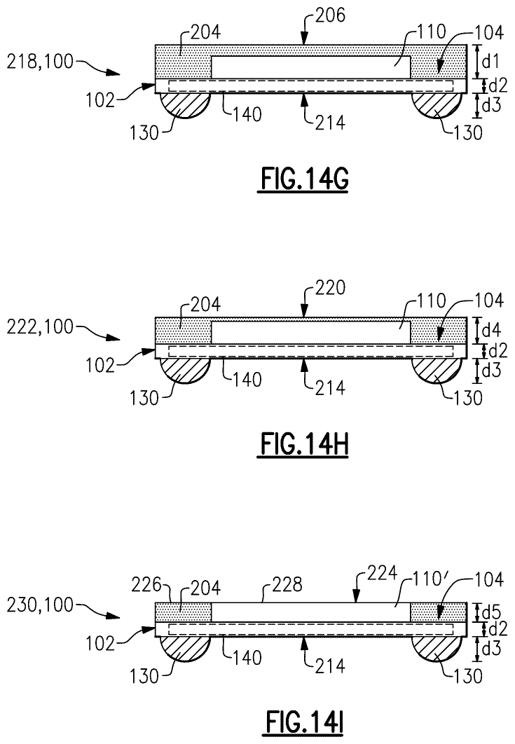

FIGS. 14A to 14F show various stages of a process that can be utilized to fabricate a packaged module having one or more features as described herein. In such an example process, ball-shaped structures (e.g., solder balls) are utilized to provide mounting and electrical connectivity functionalities for the resulting module; however, it will be understood that other structures, such as metal post structures, can also be utilized.

FIG. 14A shows a carrier layer 200 (also referred to herein as a carrier) that can be formed or provided. In some embodiments, such a carrier layer can be implemented as a metal carrier layer (also referred to herein as a metal carrier) having a lateral unit 201 in which a module will be formed.

FIG. 14B shows a stage where a die 110 is shown to be mounted on one side of the metal carrier 200 so as to form an assembly 202. In some embodiments, such a die (110) can be an acoustic wave filter die.

FIG. 14C shows a stage where a mold structure 204 is formed to partially or fully encapsulate the die 110 and define a surface 206, so as to form an assembly 208. In some embodiments, the mold structure 204 may or may not remain the same until the end of the fabrication process. If the former, the surface 206 may end up being the upper surface of the mold structure on the non-mounting side of the respective module. If the latter, the mold structure 204 may be thinned such that the original surface 206 is removed to form a new surface.

In some embodiments, the mold structure 204 of FIG. 14C can be formed using a low pressure liquid molding technique. It is noted that in embodiments where a die being encapsulated is an acoustic wave device; and such a molding technique can provide a significant impact on some or all of size, performance and reliability of the acoustic wave device.

FIG. 14D shows a stage where the metal carrier 200 in the assembly 208 of FIG. 14C is removed to provide a surface 210, so as to form an assembly 212. In some embodiments, such a removal of the metal carrier 200 can be achieved by a debonding process.

FIG. 14E shows a stage where a redistribution layers (RDL) substrate 102 is formed or provided on the surface (210 in FIG. 14D, resulting from the removal of the metal carrier) of the assembly 212, so as to form an assembly 216. In some embodiments, the foregoing RDL substrate 102 can include one or more passive elements 140 as described herein.

In some embodiments, the RDL substrate 102 can include multiple layers, and such an RDL substrate can be provided on the assembly 212 in a fully pre-fabricated form, be built on the assembly 212 based on a partially pre-fabricated form, or be built layer-by-layer on the assembly 212.

For example, suppose that an RDL substrate includes a multi-layer assembly of a first polyimide layer, a first redistribution layer, a second polyimide layer, a second redistribution layer, a third polyimide layer and an array of under-bump metallization (UBM). In the context of such an example RDL substrate, a fully pre-fabricated form having all of the foregoing parts can be provided on the assembly 212, a partially pre-fabricated form (e.g., a pre-fabricated assembly of first polyimide layer, first redistribution layer, second polyimide layer, second redistribution layer, and third polyimide layer) can be provided on the assembly 212 followed by formation of UBM array, or each of the foregoing parts can be built on the assembly 212 to form the assembly 216 of FIG. 14E.

In the example of FIG. 14E, it is noted that the RDL substrate 102 includes a first side 104 and a second side 106. The first side 104 is attached to the assembly 212 (FIG. 14D), and the second side 106 of the RDL substrate 102 is shown to be exposed, such that the assembly 216 of FIG. 14E provides a platform with a surface 214 for formation of mounting/connection pins thereon.

FIG. 14F shows a stage where ball-shaped structures 130 are implemented on the surface 214 of the assembly 216 of FIG. 14E, so as to form an assembly 218 that is generally the same as the example packaged module 100 of FIG. 13A. Accordingly, the assembly 218 of FIG. 14E is also indicated as 100.

In some embodiments, the packaged module 100 FIG. 14F can be processed further to provide a desired package thickness. For example, FIG. 14G shows the packaged module 100 of FIG. 14F in an inverted orientation relative to the orientation of FIG. 14F. Further, various example height dimensions are shown: d1 as the thickness of the mold structure 204, d2 as the thickness of the RDL substrate 102, and d3 as the height of the ball-shaped structures 130 from the RDL substrate 102. It will be understood that such a height (d3) of the ball-shaped structures 130 can result in an overall height of the packaged module 100 when it is mounted on, for example, a circuit board. Accordingly, one can see that such a mounted height of the packaged module can also be determined by the thickness dimension d1 of the mold structure 204.

FIG. 14H shows that in some embodiments, the mold structure 204 of the packaged module 100 can be thinned to provide a new thickness dimension d4 that is less than d1, to thereby provide an assembly 222. More particularly, material associated with the mold structure 204 can be removed such that the surface 206 (in FIG. 14G) is removed to provide a new surface 220 that is closer to the RDL substrate 102. In some embodiments, such a thinning process can include, for example, a grinding process.

In the example of FIG. 14H, the thinned mold structure 204 is shown to still cover the die 110. However, in some applications, it may be desirable to have the mold structure 204 be thinned further.

FIG. 14I shows that in some embodiments, the mold structure 204 of the packaged module 100 can be thinned further to provide a new thickness dimension d5 that is less than d4 of FIG. 14H, to thereby provide an assembly 230. More particularly, material associated with the mold structure 204, as well as material associated with a back side of the die 110 in some situations, can be removed such that the surface 220 (in FIG. 14H) is removed to provide a new surface 224 for the packaged module 100 that is closer to the RDL substrate 102. In some embodiments, such a thinning process can include, for example, a grinding process.

In the example of FIG. 14I, the new surface 224 is shown to include a new surface 226 of the mold structure 204 and a back side surface 228 of the die 110′. In some embodiments, the new surface 226 of the mold structure 204 and the back side surface 228 of the die 110′ are substantially co-planar.

In the example of FIG. 14I, material from the back side of the die (110 in FIG. 14H) may or may not be removed. Accordingly, the back side surface 228 of the die 110′ in FIG. 14I can be the original back side surface of the die (with no die material removed) such that the original back side surface is exposed by the thinning of the mold structure, or a new back side surface resulting from the thinning operation removing materials from the mold structure and the back side of the die.

FIG. 15 shows a packaged module 100 that is similar to the module 100 of FIG. 13A. In FIG. 13, an RDL substrate 102 of the packaged module 100 is shown to have examples of metal layers/traces, vias and pads for providing redistribution of electrical connections between a die 110 on one side of the RDL substrate 102 and pins 130 on the other side of the RDL substrate 102.

In FIG. 15, the RDL substrate 102 is shown to further include a passive element 140 as described herein. Such an RDL substrate can be similar to the RDL substrate 102 of FIG. 8.

Referring to FIGS. 15 and 8, a first side 104 of the RDL substrate 102 is shown to be configured to have the die 110 mounted thereto, and a second side 106 of the RDL substrate 102 is shown to be configured to have implemented thereon a plurality of pins 130.

It is noted that in the examples of FIGS. 14A to 14F, the non-mounting side of a module being fabricated is built first on a carrier (assembly 208 in FIG. 14C), and then an RDL substrate is provided or constructed on such a non-mounting-side portion after removal of the carrier to provide an assembly (216 in FIG. 14E) that acts as a platform for processing of the mounting side of the module being fabricated.

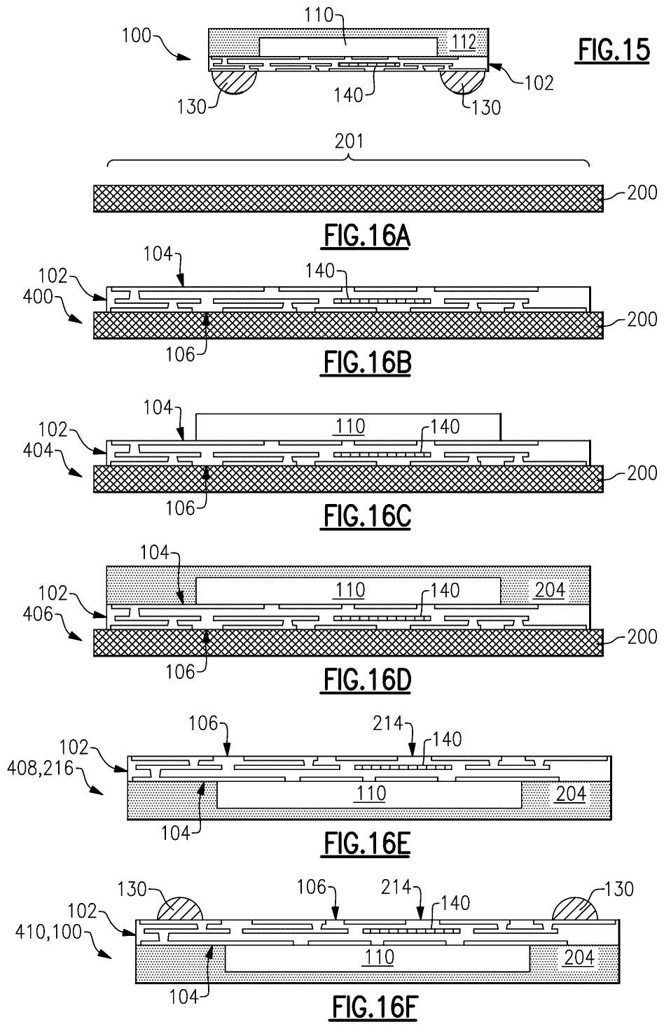

In some embodiments, a packaged module having one or more features as described herein can be fabricated by a process where an RDL substrate is provided or constructed on a carrier before building of any-side portion (e.g., non-mounting side portion) of the module. FIGS. 16A to 16F show various stages of such a process.

FIG. 16A shows a carrier layer 200 (also referred to herein as a carrier) that can be formed or provided. In some embodiments, such a carrier layer can be implemented as a metal carrier layer (also referred to herein as a metal carrier) having a lateral unit 201 in which a module will be formed.

FIG. 16B shows a stage where an RDL substrate 102 is formed or provided on the carrier 200, so as to form an assembly 400. In some embodiments, the foregoing RDL substrate 102 can include one or more passive elements 140 as described herein.

In some embodiments, the RDL substrate 102 can include multiple layers, and such an RDL substrate can be provided on the assembly 212 in a fully pre-fabricated form, be built on the assembly 212 based on a partially pre-fabricated form, or be built layer-by-layer on the assembly 212.

For example, suppose that an RDL substrate includes a multi-layer assembly of a first polyimide layer, a first redistribution layer, a second polyimide layer, a second redistribution layer, a third polyimide layer and an array of under-bump metallization (UBM). In the context of such an example RDL substrate, a fully pre-fabricated form having all of the foregoing parts can be provided on the carrier 200, a partially pre-fabricated form (e.g., a pre-fabricated assembly of first polyimide layer, first redistribution layer, second polyimide layer, second redistribution layer, and third polyimide layer) can be provided on the carrier 200 followed by formation of UBM array, or each of the foregoing parts can be built on the carrier 200 to form the assembly 400 of FIG. 16B.

In the example of FIG. 16B, it is noted that the RDL substrate 102 includes a first side 104 (e.g., a non-mounting side) and a second side 106 (e.g., a mounting side). The second side 106 is shown to be attached to the carrier 200, and the first side 106 is shown to be exposed for building of a non-mounting-side portion of a module being fabricated.

It will be understood that in some embodiments, the RDL substrate 102 can be formed or provided so that an assembly similar to the assembly 400 of FIG. 16B has the first side 104 is attached to the carrier 200, and the second side 106 is exposed for building of a mounting-side portion of a module being fabricated.

FIG. 16C shows a stage where a die 110 is mounted on the first side of the RDL substrate 102 so as to form an assembly 404. In some embodiments, such a die (110) can include an acoustic wave filter as described herein.

FIG. 16D shows a stage where a mold structure 204 is formed to partially or fully encapsulate the die 110 so as to form an assembly 406. In some embodiments, the mold structure 204 may or may not remain the same until the end of the fabrication process.

FIG. 16E shows a stage where the carrier 200 in the assembly 406 of FIG. 16D is removed to expose the second side 106 of the RDL substrate 102, so as to form an assembly 408. In some embodiments, the assembly 408 of FIG. 16E can be similar to the assembly 216 of FIG. 14E. Thus, in FIG. 16E, the assembly 408 is also indicated as 216, and the second side 106 also provides a surface 214 of the assembly 408/216.

In some embodiments, subsequent module fabrication step(s) can be similar to the example of FIG. 14F. More particularly, FIG. 16F shows a stage where ball-shaped structures 130 are implemented on the surface 214 of the assembly 408 of FIG. 16E, so as to form an assembly 410 that is generally the same as the example packaged module 100 of FIG. 13A. Accordingly, the assembly 410 of FIG. 16E is also indicated as 100.

As described herein, FIGS. 14A to 141 show various stages of one module during its fabrication process. It will be understood that in some embodiments, some or all of such a fabrication process can be performed for multiple units in an array format.

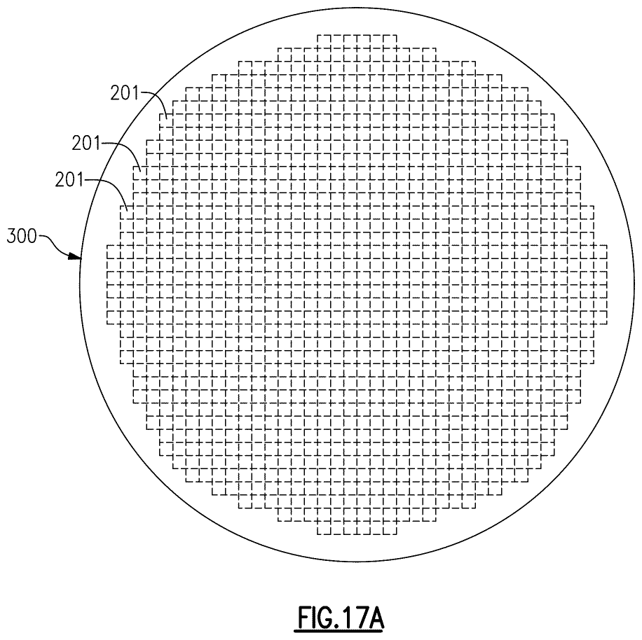

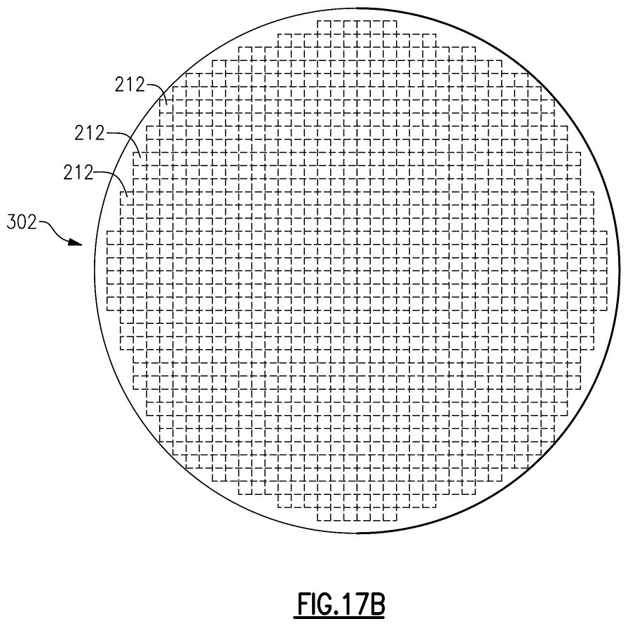

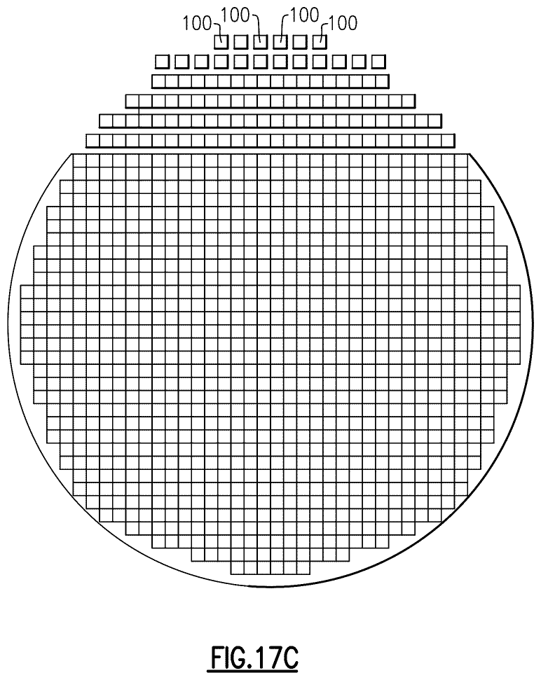

For example, FIGS. 17A to 17C show example stages of fabrication where multiple units are processed while in an array format and then singulated to provide multiple packaged units 100. More particularly, FIG. 17A shows a stage where a carrier 300 such as a wafer-shaped metal carrier is provided. Such a carrier can include an array of unit spaces 201, where each unit can be similar to the unit 201 described herein in reference to FIG. 14A.

FIG. 17B shows a stage where a die (110 in FIG. 14B) has been placed on each unit 201, a mold layer has been formed to cover the array of units, and the carrier 300 has been removed, so as to form an assembly 302 of units 212, with each unit being similar to the unit 212 of FIG. 14D. Such process steps can correspond to each unit being similar to the steps of FIGS. 14B to 14D.

FIG. 17C shows a stage where remaining process steps have been performed similar to the steps of FIGS. 14E to 14F, and the resulting array of formed modules are being singulated to provide multiple packaged modules 100.

In the examples of FIGS. 17A to 17C, the carrier 300 is depicted as having a circular shape such as a wafer shape. However, it will be understood that such a carrier can have other shapes. For example, FIGS. 18A to 18C show that in some embodiments, a rectangular shaped carrier can be utilized to fabricate an array of modules having one or more features as described herein.

More particularly, FIG. 18A shows a stage where a carrier 300 such as a rectangular-shaped metal carrier is provided. Such a carrier can include an array of unit spaces 201, where each unit can be similar to the unit 201 described herein in reference to FIG. 14A.

FIG. 18B shows a stage where a die (110 in FIG. 14B) has been placed on each unit 201, a mold layer has been formed to cover the array of units, and the carrier 300 has been removed, so as to form an assembly 302 of units 212, with each unit being similar to the unit 212 of FIG. 14D. Such process steps can correspond to each unit being similar to the steps of FIGS. 14B to 14D.

FIG. 18C shows a stage where remaining process steps have been performed similar to the steps of FIGS. 14E to 14F, and the resulting array of formed modules are being singulated to provide multiple packaged modules 100.

FIG. 19 shows that in some embodiments, one or more features of the present disclosure can be implemented in a module packaging system 500. Such a system can include a number of systems, subsystems, apparatus, etc. configured to provide respective functionalities. For example, a panel handling component 502 can be provided to allow handling of carriers, substrate panels and/or panel assemblies having mold layer(s) thereon.

In another example, an assembly component 504 can be provided to, for example, mounting of devices on at least one side (e.g., non-mounting side) of substrate panels, and formation of conductive features on at least one side (e.g., mounting side) side of substrate panels. In some embodiments, such an assembly functionality can be supported by, for example, a pick-and-place apparatus 506 in operation with a controller 508.

In yet another example, a panel mold component 510 can be provided to form some or all of panel mold layers as described herein. In some embodiments, such panel mold layer forming component can be configured to form a mold layer on at least one side of substrate panels.

In yet another example, a thinning component 512 can be provided to allow thinning of panel mold layers as described herein. In some embodiments, such thinning component can include a grinding functionality to remove material from a panel mold layer. In some embodiments, the grinding functionality can also include removal of material from back sides of die that are at least partially encapsulated by the panel mold layer.

In yet another example, a singulation component 514 can be provided to perform singulation operations on completed panel assemblies.

In some embodiments, some or all of the functional components of the module packaging system 500 of FIG. 19 can be performed under the control of, and/or facilitated by, a computer configured to execute one or more algorithms.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A packaged module comprising:
a substrate having first and second sides, and a plurality of redistribution layers;
a filter die implemented on the first side of the substrate, and a plurality of pins implemented on the second side of the substrate, such that the redistribution layers include a fan out circuit between the filter die and the pins; and
a passive element implemented as part of the redistribution layers and configured to support operation of the filter die.

2. The packaged module of claim 1 further comprising a mold structure implemented on the first side of the substrate to at least partially encapsulate the filter die.

3. The packaged module of claim 2 wherein the mold structure is configured to completely encapsulate the filter die.

4. The packaged module of claim 2 wherein the mold structure is configured to expose a back side of the filter die.

5. The packaged module of claim 4 wherein the mold structure includes a surface that exposes the back side of the filter die, the surface of the mold structure being formed from a thinning operation.

6. The packaged module of claim 5 wherein the exposed back side of the filter die is formed from removal of at least some material from the back side of the filter die.

7. The packaged module of claim 5 wherein the exposed back side of the filter die and the surface of the mold structure are substantially co-planar.

8. The packaged module of claim 2 wherein the mold structure is formed from a low pressure liquid molding process.

9. The packaged module of claim 1 wherein the plurality of redistribution layers includes a first outermost layer that defines the first side and a second outermost layer that defines the second side.

10. The packaged module of claim 9 wherein the filter die is implemented directly on the first side, and the pins are implemented directly on the second side.

11. The packaged module of claim 1 wherein the pins are implemented as ball-shaped structures.

12. The packaged module of claim 11 wherein the ball-shaped structures are implemented as solder balls.

13. The packaged module of claim 1 wherein the pins are implemented as metal posts.

14. The packaged module of claim 13 wherein the metal posts are implemented as copper posts.

15. The packaged module of claim 1 wherein the filter die is mounted on the first side of the substrate to provide a no-gap configuration therebetween.

16. The packaged module of claim 15 wherein the filter die includes a mounting side that is patterned to allow the mounting side to be mated directly with a corresponding patterned area on the first side of the substrate.

17. The packaged module of claim 1 wherein the passive element is implemented as one or more features printed on one or more layers of the redistribution layers.

18. The packaged module of claim 1 wherein the passive element includes an inductor, a capacitor or a resistor.

19. The packaged module of claim 18 wherein the passive element is configured to provide a radio-frequency functionality with respect to the filter die.

20. The packaged module of claim 19 wherein the radio-frequency functionality includes a matching functionality.

21. The packaged module of claim 19 wherein the passive element is configured to provide the radio-frequency functionality with a desired quality factor.

22. The packaged module of claim 18 wherein the passive element is implemented on a selected layer of the redistribution layers.

23. The packaged module of claim 22 wherein the selected layer includes a layer at or closest to the first side of the substrate.

24. The packaged module of claim 22 wherein the selected layer includes a layer adjacent to a layer associated with the first side of the substrate.

25. The packaged module of claim 1 further comprising another passive element implemented as part of the redistribution layers and configured to support operation of the filter die.

26. The packaged module of claim 25 wherein the passive element and the other passive element are implemented on a common layer.

27. The packaged module of claim 25 wherein the passive element and the other passive element are implemented on different layers.

28. The packaged module of claim 1 wherein the passive element is implemented to provide a lateral footprint that at least partially overlaps with a lateral footprint of the filter die to allow reduction of lateral dimensions of the packaged module.

29. The packaged module of claim 1 wherein the filter die is implemented as an acoustic wave filter die.

30. The packaged module of claim 29 wherein the acoustic wave filter die includes a surface acoustic wave (SAW) filter.

31. The packaged module of claim 29 wherein the acoustic wave filter die includes a bulk acoustic wave (BAW) filter.

32. The packaged module of claim 29 wherein the acoustic wave filter die includes a multilayer piezoelectric substrate (MPS) filter.

33. The packaged module of claim 1 further comprising another filter die implemented on the first side of the substrate.

34. The packaged module of claim 33 wherein each of the filter die and the other filter die is implemented as an acoustic wave filter die.

35. The packaged module of claim 34 wherein the acoustic wave filter die and the other acoustic wave filter die are implemented as same type of acoustic wave filter device.

36. The packaged module of claim 34 wherein the acoustic wave filter die and the other acoustic wave filter die are implemented as different types of acoustic wave filter devices.

37. A method for manufacturing a packaged module, the method comprising:
providing a carrier;
forming a first-side portion of a module on the carrier;
removing the carrier from the first-side portion to provide a surface;
providing or forming a substrate having redistribution layers on the first-side portion, such that the redistribution layers include a passive element, and such that a first side of the substrate engages the surface of the first-side portion and a second side of the substrate is opposite from the first side; and
forming a second-side portion of the module on the second side of the substrate.

38. The method of claim 37 wherein the forming of the first-side portion includes attaching a filter die on a surface of the carrier, and forming a mold structure over the surface of the carrier to at least partially encapsulate the filter die.

39. The method of claim 38 wherein the forming of the mold structure results in the mold structure fully encapsulating the filter die.

40. The method of claim 38 wherein the forming of the mold structure results in the mold structure exposing a back side of the filter die.

41. The method of claim 40 wherein the forming of the mold structure includes a mold forming process that results in the mold structure fully encapsulating the filter die, and a thinning process that results in the mold structure being thinned to expose the back side of the filter die.

42. The method of claim 41 wherein the thinning process includes a grinding process.

43. The method of claim 41 wherein the thinning process results in the exposed back side of the filter die being formed from removal of at least some material from the back side of the filter die.

44. The method of claim 41 wherein the thinning process results in the exposed back side of the filter die and the surface of the mold structure being substantially co-planar.

45. The method of claim 37 wherein the removing of the carrier from the first-side portion includes a debonding process.

46. The method of claim 37 wherein the substrate is a pre-fabricated substrate having multiple layers such that a first outermost layer defines the first side and a second outermost layer defines the second side.

47. The method of claim 46 wherein the first side of the substrate directly engages the surface of the first-side portion.

48. The method of claim 46 wherein the first side of the substrate engages a mounting surface of a filter die of the first-side portion to provide a gapless interconnect between the filter die and the first side of the substrate.

49. The method of claim 37 wherein the substrate is formed over the surface of the first-side portion.

50. The method of claim 49 wherein the forming of the substrate includes forming multiple layers such that a first outermost layer defines the first side and a second outermost layer defines the second side.

51. The method of claim 50 wherein the first side of the substrate directly engages the surface of the first-side portion including a filter die.

52. The method of claim 51 wherein the first side of the substrate engages a mounting surface of the filter die to provide a gapless interconnect between the filter die and the first side of the substrate.

53. The method of claim 37 wherein the forming of the second-side portion includes implementing a plurality of pins on the second side of the substrate.

54. The method of claim 37 wherein the carrier includes a metal carrier.

55. The method of claim 37 wherein the carrier is dimensioned to allow processing of an array of units each including a respective first-side portion, such that an array of packaged modules are manufactured while in an array format.

56. The method of claim 55 further comprising singulating the array of packaged modules into a plurality of individual packaged modules.

57. The method of claim 37 wherein the forming or providing of the substrate includes the passive element being implemented as one or more features printed on one or more layers of the redistribution layers.

58. The method of claim 37 wherein the passive element includes an inductor, a capacitor or a resistor.

59. The method of claim 58 wherein the passive element is configured to provide a radio-frequency functionality with respect to a filter die of the first-side portion.

60. The method of claim 59 wherein the radio-frequency functionality includes a matching functionality.

61. The method of claim 59 wherein the passive element is configured to provide the radio-frequency functionality with a desired quality factor.

62. The method of claim 58 wherein the passive element is implemented on a selected layer of the redistribution layers.

63. The method of claim 62 wherein the selected layer includes a layer at or closest to the first side of the substrate.

64. The method of claim 62 wherein the selected layer includes a layer adjacent to a layer associated with the first side of the substrate.

65. The method of claim 37 wherein the providing or forming of the substrate further includes implementing another passive element as part of the redistribution layers.

66. The method of claim 65 wherein the passive element and the other passive element are implemented on a common layer.

67. The method of claim 65 wherein the passive element and the other passive element are implemented on different layers.

68. The method of claim 37 wherein the passive element is implemented to provide a lateral footprint that at least partially overlaps with a lateral footprint of a filter die of the first-side portion to allow reduction of lateral dimensions of the packaged module.

69. The method of claim 37 wherein the first-side portion includes an acoustic wave filter die.

70. The method of claim 69 wherein the acoustic wave filter die includes a surface acoustic wave (SAW) filter, a bulk acoustic wave (BAW) filter, or a multilayer piezoelectric substrate (MPS) filter.

71. The method of claim 69 wherein the first-side portion further includes another acoustic wave filter die.

72. The method of claim 71 wherein the acoustic wave filter die and the other acoustic wave filter die are implemented as same type of acoustic wave filter device.

73. The packaged module of claim 71 wherein the acoustic wave filter die and the other acoustic wave filter die are implemented as different types of acoustic wave filter devices.

74. A method for manufacturing packaged modules, the method comprising:
providing a carrier;
providing or forming a substrate having first and second sides and redistribution layers on the carrier, such that the redistribution layers include a passive element, and such that the second side engages the carrier;
forming a first-side portion of a module on the first side of the substrate;
removing the carrier from the second side of the substrate; and
forming a second-side portion of the module on the second side of the substrate.

75. The method of claim 74 wherein the forming of the first-side portion includes attaching a filter die on the first side of the substrate, and forming a mold structure over the first side of the substrate to at least partially encapsulate the filter die.

76. The method of claim 74 wherein the removing of the carrier from the second side of the substrate includes a debonding process.

77. The method of claim 74 wherein the substrate is a pre-fabricated substrate having multiple layers such that a first outermost layer defines the first side and a second outermost layer defines the second side.

78. The method of claim 77 wherein the first side of the substrate directly engages the surface of the first-side portion.

79. The method of claim 77 wherein the first side of the substrate engages a mounting surface of a filter die of the first-side portion to provide a gapless interconnect between the filter die and the first side of the substrate.

80. The method of claim 74 wherein the substrate is formed over the surface of the carrier.

81. The method of claim 80 wherein the forming of the substrate includes forming multiple layers such that a first outermost layer defines the first side and a second outermost layer defines the second side.

82. The method of claim 81 wherein the first side of the substrate directly engages the surface of the first-side portion including a filter die.

83. The method of claim 82 wherein the first side of the substrate engages a mounting surface of the filter die to provide a gapless interconnect between the filter die and the first side of the substrate.

84. The method of claim 74 wherein the forming of the second-side portion includes implementing a plurality of pins on the second side of the substrate.

85. The method of claim 74 wherein the carrier includes a metal carrier.

86. The method of claim 74 wherein the carrier is dimensioned to allow processing of an array of units each including a respective substrate and a respective first-side portion, such that an array of packaged modules are manufactured while in an array format.

87. The method of claim 86 further comprising singulating the array of packaged modules into a plurality of individual packaged modules.

88. The method of claim 74 wherein the forming or providing of the substrate includes the passive element being implemented as one or more features printed on one or more layers of the redistribution layers.

89. The method of claim 74 wherein the passive element includes an inductor, a capacitor or a resistor.

90. The method of claim 89 wherein the passive element is configured to provide a radio-frequency functionality with respect to a filter die of the first-side portion.

91. The method of claim 90 wherein the radio-frequency functionality includes a matching functionality.

92. The method of claim 90 wherein the passive element is configured to provide the radio-frequency functionality with a desired quality factor.

93. The method of claim 89 wherein the passive element is implemented on a selected layer of the redistribution layers.

94. The method of claim 93 wherein the selected layer includes a layer at or closest to the first side of the substrate.

95. The method of claim 93 wherein the selected layer includes a layer adjacent to a layer associated with the first side of the substrate.

96. The method of claim 74 wherein the providing or forming of the substrate further includes implementing another passive element as part of the redistribution layers.

97. The method of claim 96 wherein the passive element and the other passive element are implemented on a common layer.

98. The method of claim 96 wherein the passive element and the other passive element are implemented on different layers.

99. The method of claim 74 wherein the passive element is implemented to provide a lateral footprint that at least partially overlaps with a lateral footprint of a filter die of the first-side portion to allow reduction of lateral dimensions of the packaged module.

100. The method of claim 74 wherein the first-side portion includes an acoustic wave filter die.

101. The method of claim 100 wherein the acoustic wave filter die includes a surface acoustic wave (SAW) filter, a bulk acoustic wave (BAW) filter, or a multilayer piezoelectric substrate (MPS) filter.

102. The method of claim 100 wherein the first-side portion further includes another acoustic wave filter die.

103. The method of claim 102 wherein the acoustic wave filter die and the other acoustic wave filter die are implemented as same type of acoustic wave filter device.

104. The packaged module of claim 102 wherein the acoustic wave filter die and the other acoustic wave filter die are implemented as different types of acoustic wave filter devices.
